(19) United States
(12) Patent Application Publication
(10) Pub. No.: US 2017/0262337 A1
(43) Pub. Date: Sep. 14, 2017

(54) MEMORY MODULE REPAIR SYSTEM WITH FAILING COMPONENT DETECTION AND METHOD OF OPERATION THEREOF

(71) Applicant: SMART Modular Technologies, Inc., Newark, CA (US)

(72) Inventors: Reuben J. Chang, Campbell, CA (US); Satyanarayan S. Iyer, Fremont, CA (US); Michael Rubino, San Jose, CA (US)

(21) Appl. No.: 15/066,728

(22) Filed: Mar. 10, 2016

(51) Int. Cl. G06F 11/10; G11C 29/52; G11C 29/04; G06F 13/24

(52) U.S. Cl. CPC G06F 11/1076; G06F 13/24; G11C 29/52; G11C 29/04

(57) ABSTRACT

A memory module repair system, and a method of operation thereof, including: a memory controller; a volatile memory having memory chips coupled to the memory controller, the memory controller for testing the volatile memory; an ECC controller, coupled to the memory controller, for determining a failing bit location information of a failing bit within the volatile memory; and an error log storage coupled to the memory controller and the ECC controller for storing the failing bit location information.

### TECHNICAL FIELD

The present invention relates generally to a memory module repair system, and more particularly to a system for detection of failing components.

### BACKGROUND ART

There is a continual need in the area of electronics and electronic computing systems toward smaller systems and/or systems with greater computing performance for a given space and within a given power profile. Within these systems, the integrated circuit and memory modules are the building block used in high performance electronic systems to provide applications for usage in products such as automotive vehicles, computers, cell phone, intelligent portable military devices, aeronautical spacecraft payloads, and a vast line of other similar products that require small compact electronics supporting many complex functions.

Products must compete in world markets and attract many consumers or buyers in order to be successful. It is very important for products to continue to improve in features, performance, and reliability while reducing product costs, product size, and to be available quickly for purchase by the consumers or buyers. Manufacturing improvements may increase reliability of a product itself, but there are times when near absolute reliability is desired. Wholesale replacement of memory modules remains an expensive way to obtain the desired reliability.

Thus, a need still remains for a system to reliably and quickly repair memory modules and ensure reliability. In view of the growing importance of reliable and accurate calculations, it is increasingly critical that answers be found to these problems. In view of the ever-increasing commercial competitive pressures, along with growing consumer expectations and the diminishing opportunities for meaningful product differentiation in the marketplace, it is critical that answers be found for these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a method of operation of a memory module repair system that includes providing a memory controller coupled to an ECC controller and an error log storage, the memory controller coupled to a volatile memory; testing the volatile memory, the volatile memory having memory chips; determining a failing bit location information of a failing bit within the volatile memory with the ECC controller; and storing the failing bit location information within the error log storage.

The present invention provides a memory module repair system that includes a memory controller; a volatile memory having memory chips coupled to the memory controller, the memory controller for testing the volatile memory; an ECC controller, coupled to the memory controller, for determining a failing bit location information of a failing bit within the volatile memory; and an error log storage coupled to the memory controller and the ECC controller for storing the failing bit location information.

Certain embodiments of the invention have other steps or elements in addition to or in place of those mentioned above. The steps or element will become apparent to those skilled in the art from a reading of the following detailed description when taken with reference to the accompanying drawings.

### BRIEF DESCRIPTION OF THE DRAWINGS

FIG. 1 is a functional block diagram of a memory module repair system with failing component detection in an embodiment of the present invention.

FIG. 2 is a flow chart of a method of operation of a memory module repair system in a further embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGs. Similarly, although the views in the drawings for ease of description generally show similar orientations, this depiction in the FIGs. is arbitrary for the most part. Generally, the invention can be operated in any orientation.

Where multiple embodiments are disclosed and described having some features in common, for clarity and ease of illustration, description, and comprehension thereof, similar and like features one to another will ordinarily be described with similar reference numerals. The embodiments have been numbered first embodiment, second embodiment, etc. as a matter of descriptive convenience and are not intended to have any other significance or provide limitations for the present invention.

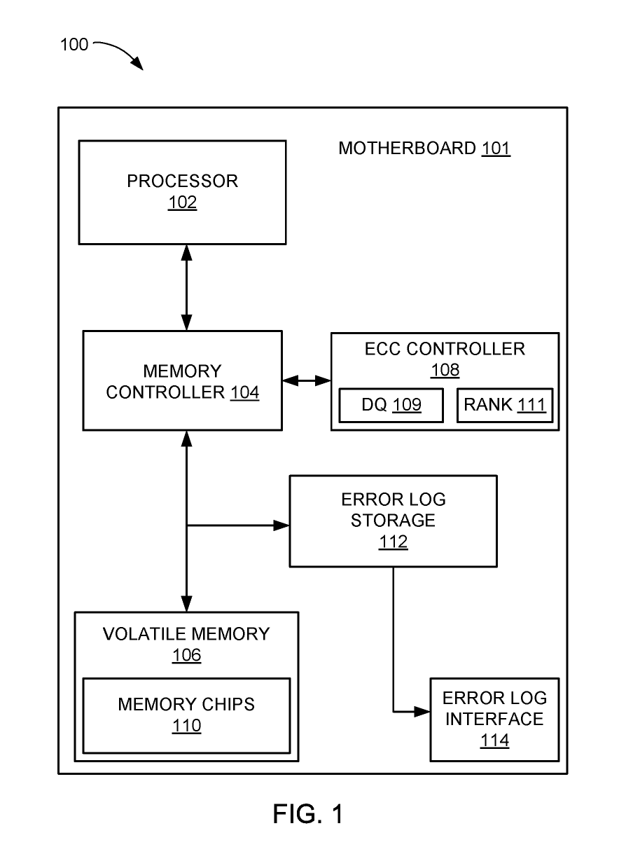

Referring now to FIG. 1, therein is shown a functional block diagram of a memory module repair system 100 with failing component detection in an embodiment of the present invention. The memory module repair system 100 can include a motherboard 101, a processor 102, a memory controller 104, volatile memory 106, an ECC controller 108, and an error log storage 112.

As an example, the volatile memory 106 can be a memory module which is some type of DDR SDRAM (Double Data Rate Synchronous Random Access Memory; for example: DDR3 SDRAM, DDR4 SDRAM, etc.) with ECC (error correcting code) capability. Of course, the volatile memory 106 can be any type of random access memory. The volatile memory 106 can be controlled by the memory controller 104 which can operate together with an ECC controller 108. The volatile memory 106 can include a number of memory chips 110 since the volatile memory 106 can consist of an array of volatile memory chips to reach a desired storage capacity. For illustrative purposes, the volatile memory 106 is described as a single memory module, but it is understood that the motherboard 101 can have multiple slots for connection of multiple memory modules.

The memory controller 104 can function as the hub of communication between various components on or connected to the motherboard 101. The processor 102 is used for normal operation of the motherboard 101 and can be connected to the board controller 104. The volatile memory 106 is also connected to the board controller 104 through the memory controller 104. The motherboard 101 can be part of a larger host device (not shown). Also connected to the memory controller 104 is the error log storage 112. The error log storage 112 can be integral to the motherboard 101 or can be connected through an interface and can be some kind of system error log, register, or connected storage drive, for example.

Under regular operation, the ECC controller 108, which can also be referred to as error detection and correction circuitry (EDAC), operates to identify bit errors within the memory chips 110 of the volatile memory 106 and correct them. In order to do so, the ECC controller 108 must know the physical location of the failing bit or bits, which is also known as DQ, or a failing bit location information 109, in order to correct the error. Rank information 111 is also generally necessary for the ECC controller 108 to operate properly. Additionally, while the memory controller 104, the processor 102, and the ECC controller 108 are shown as separate in the drawing, it is also possible for all of these components to be integrated into the main CPU attached to the motherboard 101.

Identifying the DQ, or the location of the failing bit, is information which is generally not seen outside the ECC controller 108. Modifications can be made to the BIOS (basic input/output system) of the motherboard 101 in order to extract the rank information 111 and the failing bit location information 109 (DQ) for storage in the error log storage 112 as the memory module repair system 100 is run under various temperature ranges. The processor 102 can execute commands from the BIOS, for example. A system level stress test can be run with the volatile memory 106 attached to the motherboard 101; this can be also referred to as a burn-in process. The memory chips 110 of the volatile memory 106 can be stressed using various tests at various temperatures (room temperature, hot or cold temperatures, for example) which replicate real-world conditions as well as extending well beyond them to simulate accelerated stress conditions to better determine failing chips. As an additional example, the volatile memory 106 can be stressed using other stressors such as voltage instability, physical impact, overclocking, timing margins, or other various test applications which are specifically designed to accelerate failures of weak components.

The modifications made to the BIOS of the motherboard 101 can cause the processor 102 to generate an interrupt when the ECC controller 108 activates due to a bit error. This interrupt allows the memory controller 104 or the processor 102 to capture the failing bit location information 109 (DQ) and the rank information 111 for storage in the error log storage 112. The stress test can be run until its completion whereupon the error log storage 112 can be read to determine the location of every failing bit. Once the failing bit location information 109 and the rank information 111 is known, it is possible to determine which of the memory chips 110 has a bad bit, such that replacement of that particular memory chip or chips can result in a more robust and higher-quality memory module after the repair.

It has been discovered that the use of the ECC controller 108 in order to extract the failing bit location information for storage in the error log storage 112 allows for the creation of a robust and high-quality memory module for use as the volatile memory 106. Use of the failing bit location information 109 and the rank information 111 from the ECC controller 108 and stored in the error log storage 112 allows for replacement of only the failing memory chips of the volatile memory 106 and for the creation through repair of a memory module which is now sure to be of good reliability.

It has also been discovered that the use of the ECC controller 108 on the motherboard 101 to perform system-level testing on the memory chips 110 of the volatile memory 106 provides both high reliability modules and reduces scrap cost. While automated testing equipment for memory modules exists, such equipment is not the same as testing the volatile memory 106 on a system which replicates real-world stresses; system-level testing on a motherboard identical to one used in regular systems can uncover bit errors which do not show up while using automated testing equipment. The stresses placed on the memory chips 110 of the volatile memory 106 when running system-level testing cannot be replicated by automated testing equipment. This can result in passing memory chips which contain latent failures which will remain undetected until live usage in actual servers; this does not produce high reliability modules. Additionally, some automated testing equipment determines a failure of the memory module, which results in the entire memory module being scrapped. Since the memory module consists of a number of the memory chips 110, most of which are probably good and do not need to be thrown away, this results in a lot of waste and increased costs. Replacement of only the failing memory chips when using the memory module repair system 100 allows the good memory chips to be saved, provides for less wasted material, and introduces the ability to create memory chips of even greater reliability through the repair of what appeared to be a bad memory module.

It is also been discovered that the use of the ECC controller 108 within the memory module controller 107 can be applied to find weak or failing components on boards other than server motherboards. For example, this methodology can be used to produce reliable overclocked parts; overclocking a chip can put a great deal of stress on it, and some parts will handle such stresses better than others. To extend this example, gaming performance is directly tied to the clock speed of the volatile memory and the chips on the gaming board. Those who expect high performance may be willing to pay a premium for overclocked gaming modules with guaranteed performance and reliability. Determining which of the memory chips 110 within the volatile memory 106 of a gaming board need to be replaced in order to reliably reach overclocked speeds can allow a manufacturer to produce gaming boards which can reach a guaranteed level of overclocked performance without failure. This is because any of the memory chips 110 which may not be of good enough quality to deal with the stresses of overclocking will have been replaced by a stronger part.

In other words, components can be arranged and connected as they would on the motherboard 101 of an end-user. These components including the volatile memory 106 can be stress tested at a system-level the variations of temperature, voltage, or clock speed, for example. The ECC controller 108 within the memory module controller 107 can identify the DQ or the failing bit location information 109 and the rank information 111 of the failing bit or bits within the memory chips 110 of the volatile memory 106. The BIOS of the motherboard 101 can be configured such that the processor 102 or the memory controller 104 can generate an interrupt as soon as the ECC controller 108 identifies an error. The failing bit location information 109 in the rank information 111 to be extracted and stored within the error log storage 112. The entire stress test can be run and then the error log storage 112 can be retrieved, the particular memory chips within the volatile memory 106 which are failing identified, and the failing memory chips can be replaced, completing the repair of the volatile memory 106. The failing bit location information 109 and the rank information 111 within the error log storage 112 can be retrieved through an error log interface 114, which is coupled to the error log storage 112. The error log interface 114 can be internal or external to the motherboard 101, and can be connected or coupled wirelessly or through a physical interconnect.

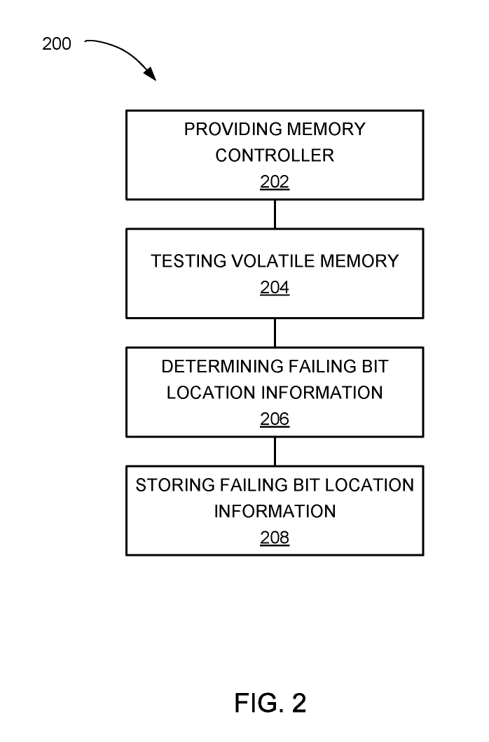

Referring now to FIG. 2, therein is shown a flow chart of a method 200 of operation of a memory module repair system in a further embodiment of the present invention. The method 200 includes: providing a memory controller coupled to an ECC controller and an error log storage, the memory controller coupled to a volatile memory in a block 202; testing the volatile memory, the volatile memory having memory chips in a block 204; determining a failing bit location information of a failing bit within the volatile memory with the ECC controller in a block 206; and storing the failing bit location information within the error log storage in a block 208.

The resulting method, process, apparatus, device, product, and/or system is straightforward, cost-effective, uncomplicated, highly versatile, accurate, sensitive, and effective, and can be implemented by adapting known components for ready, efficient, and economical manufacturing, application, and utilization.

Another important aspect of the present invention is that it valuably supports and services the historical trend of reducing costs, simplifying systems, and increasing performance.

These and other valuable aspects of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of operation of a memory module repair system comprising:
providing a memory controller coupled to an ECC controller and an error log storage, the memory controller coupled to a volatile memory;
testing the volatile memory, the volatile memory having memory chips;
determining a failing bit location information of a failing bit within the volatile memory with the ECC controller; and
storing the failing bit location information within the error log storage.

2. The method as claimed in claim 1 further comprising:
retrieving the failing bit location information from the error log storage;
determining a failing memory chip by determining which of the memory chips of the volatile memory is associated with the failing bit location information; and
replacing the failing memory chip.

3. The method as claimed in claim 1 further comprising determining a rank information of the failing bit within the volatile memory with the ECC controller.

4. The method as claimed in claim 1 wherein testing the volatile memory includes running the volatile memory under various temperatures, voltages, or clock speeds.

5. The method as claimed in claim 1 further comprising coupling a processor to the memory controller.

6. A method of operation of a memory module repair system comprising:
providing a memory controller coupled to an ECC controller and an error log storage, the memory controller coupled to a volatile memory;
testing the volatile memory, the volatile memory having memory chips;
determining a failing bit location information and a rank information of a failing bit within the volatile memory with the ECC controller;
storing the failing bit location information and the rank information within the error log storage;
retrieving the failing bit location information and the rank information from the error log storage;
determining a failing memory chip by determining which of the memory chips of the volatile memory is associated with the failing bit location information and the rank information; and
replacing the failing memory chip.

7. The method as claimed in claim 6 wherein storing the failing bit location information includes storing the failing bit location information within an error log register.

8. The method as claimed in claim 6 further comprising generating an interrupt based on determining the failing bit location information with the ECC controller.

9. The method as claimed in claim 6 wherein testing the volatile memory includes system-level stress testing of the volatile memory.

10. The method as claimed in claim 6 wherein storing the failing bit location information includes storing the failing bit location information within an external storage device.

11. A memory module repair system comprising:
a memory controller;
a volatile memory having memory chips coupled to the memory controller, the memory controller for testing the volatile memory;
an ECC controller, coupled to the memory controller, for determining a failing bit location information of a failing bit within the volatile memory; and
an error log storage coupled to the memory controller and the ECC controller for storing the failing bit location information.

12. The system as claimed in claim 11 further comprising an error log interface coupled to the error log storage for retrieving the failing bit location information from the error log storage.

13. The system as claimed in claim 11 wherein the ECC controller is for determining a rank information of the failing bit within the volatile memory.

14. The system as claimed in claim 11 wherein the memory controller is for testing the volatile memory at various voltages.

15. The system as claimed in claim 11 further comprising a processor coupled to the memory controller.

16. The system as claimed in claim 11 further comprising:
an error log interface coupled to the error log storage;
a processor coupled to the memory controller; and
wherein:
the ECC controller is for determining a rank information of the failing bit within the volatile memory.

17. The system as claimed in claim 16 wherein the error log storage is an error log register.

18. The system as claimed in claim 16 further comprising a basic input/output system for generating an interrupt based on determining the failing bit location information with the ECC controller.

19. The system as claimed in claim 16 wherein the error log storage is a hard drive or solid state drive.

20. The system as claimed in claim 16 wherein the error log storage is an external storage device.
